(19) United States
(12) Patent Application Publication
(10) Pub. No.: US 2004/0180295 A1
(43) Pub. Date: Sep. 16, 2004

(54) Method for fabricating a dual damascene structure using a single photoresist layer

(76) Inventor: Sheng-Yueh Chang, Taipei Hsien (TW)

Correspondence Address: NAIPO (NORTH AMERICA INTERNATIONAL PATENT OFFICE), P.O. BOX 506, MERRIFIELD, VA, 22116, US

(21) Appl. No.: 10/249,006

(22) Filed: Mar. 10, 2003

(51) Int. Cl. G03F 7/26

(52) U.S. Cl. 430/313; 430/311

(57) ABSTRACT

A photo-sensitive material layer is formed over a semiconductor substrate. The photo-sensitive material layer is exposed to a first radiation having a maximum intensity at a first wavelength to form a first latent pattern in the photo-sensitive material layer. The photo-sensitive material layer is then exposed to a second radiation having a maximum intensity at a second wavelength to form a second latent pattern in the photo-sensitive material layer. The first latent pattern and the second latent pattern in the photo-sensitive material layer are then simultaneously removed.

### BACKGROUND OF INVENTION

1. Field of the Invention

The present invention relates generally to a lithographic method, and more particularly, to an improved lithographic method for fabricating a dual damascene structure in a dielectric layer that involves only one photoresist coating step, two consecutive exposure steps, one development step, and one etching step.

2. Description of the Prior Art

Dual damascene techniques have been developed to simplify the process steps required to form electrical interconnect structures in a traditional plug-type interconnect fabrication process. A dual damascene structure has a bottom via portion that contacts an underlying conductor and a top inlaid trench structure used for the formation of a second conductor. Because the bottom and top portions of a dual damascene structure are in contact with each other, they can be filled simultaneously with the same conductive material, such as copper. This obviates the need to form a plug structure and an overlying conductive layer in separate processing steps, and also renders the dual damascene techniques useful in copper wiring architectures.

Please refer to FIG. 1. FIG. 1 is a schematic cross-sectional diagram of a semiconductor wafer 10 showing a conventional dual damascene structure 11. As shown in FIG. 1, a bottom copper conductor 14 is damascened in a first low-k material layer 12 and a top copper conductor 24 is damascened in a trench structure 23 in a second low-k material layer 20. The top copper conductor 24 is connected with the bottom copper conductor 14 with a via structure 22 of the dual damascene structure 11. However, conventional dual damascene processes are complex and thus lead to low throughput. For example, a via-first dual damascene process typically needs two photoresist coating steps, one bottom anti-reflective coating (BARC) step, two separate exposure steps, two development steps, and two etching steps, to complete a dual damascene structure in a dielectric layer.

Please refer to FIG. 2 to FIG. 8. FIG. 2 to FIG. 8 are schematic diagrams showing the process of fabricating a via-first dual damascene structure in a dielectric layer 34. First, as shown in FIG. 2, a semiconductor wafer 30, which comprises a substrate 32 and the dielectric layer 34 formed over the substrate 32, is provided. The dielectric layer 34 may be made of HSQ, FLARE™, SiLK™, or the like.

As shown in FIG. 3, a 1 μm thick positive photoresist layer 36, such as an i-line (365 nm) photoresist, a KrF (248 nm) photoresist, an ArF (193 nm) photoresist, or a 157 nm photoresist, is spin-coated onto the dielectric layer 34. Basically, the demands of resolution and design rule determine the type of the positive photoresist layer 36. A dehydration bake or at least one soft bake step is thereafter used to enhance the precision of the pattern. A latent via pattern or a latent image 37, which is basically composed of rearranged compounds, is then created in the positive photoresist layer 36 using a mask 39 having a via pattern and incident exposure rays 38 at a specific wavelength. The wavelength of the incident exposure ray 38 is chosen according to the type of the positive photoresist layer 36.

Subsequently, as shown in FIG. 4, a development step is performed. A developer, typically an alkaline solution, is used to dissolve the latent via pattern 37, while the unexposed portions of the photoresist layer 36 are substantially not affected by the developer. A hard bake step is then used to dislodge solvents from the positive photoresist layer 36. Next, using the developed positive photoresist layer 36 as an etch mask, a first anisotropic etching process is performed to transfer the via pattern in the photoresist layer 36 to the underlying dielectric layer 34, so as to form a via 41 in the dielectric layer 34. The photoresist layer 36 is then removed.

As shown in FIG. 5, a BARC etch block 42 is formed at the bottom of the via 41. One purpose of the BARC etch block 42 is to reduce thin-film interference effects in the following trench patterning process. Next, a 1 μm thick positive photoresist layer 46 is coated. As shown in FIG. 6, a latent trench pattern 47 is then created in the positive photoresist layer 46 using a mask 49 having a trench pattern and incident exposure rays 48 at a specific wavelength. Likewise, the wavelength of the incident exposure rays 48 is chosen according to the type of the positive photoresist layer 46.

As shown in FIG. 7, a development step is performed to dissolve the latent trench pattern 47. A hard bake step is then used. Next, using the developed positive photoresist layer 46 as an etch mask, a second anisotropic etching process is performed to transfer the trench pattern in the photoresist layer 46 to the underlying dielectric layer 34, so as to form a trench pattern 51 in the dielectric layer 34. Finally, as shown in FIG. 8, the positive photoresist layer 46 and the BARC etch block 42 are removed using known skills in the art.

As mentioned, conventional dual damascene processes, for example, a via-first dual damascene process, typically need two photoresist coating steps, two separate exposure steps, two development steps, and two etching steps, to complete a dual damascene structure in a dielectric layer. As such, the conventional dual damascene process is costly, time-consuming, and leads to an unsatisfactory production throughput and poor pattern transfer precision. Additionally, the use of the BARC etch block 42 is subject to a problem of uniform coating, thereby further affecting production yields.

### SUMMARY OF INVENTION

It is therefore a primary objective of this invention to provide a method for fabricating a dual damascene structure so as to solve the above-mentioned problems.

Another objective of the invention is to provide a method for constructing a dual damascene structure in a dielectric layer using a single positive photoresist layer and a dual-wavelength exposure technique.

Still another objective of the invention is to provide a method for constructing a dual damascene structure in a dielectric layer using only one photoresist coating step, two consecutive exposure steps, one development step, and one etching step, but without the use of a BARC etch block.

In accordance with the present invention, a preferred embodiment of the present invention comprises the following steps:

1) Providing a semiconductor substrate.

2) Forming a photo-sensitive material layer over the semiconductor substrate. The photo-sensitive material layer presents a first absorbance at a first wavelength, and presents a second absorbance at a second wavelength upon exposure to incident light.

3) Exposing the photo-sensitive material layer to a first radiation that has a maximum intensity at the first wavelength to form a first latent pattern in the photo-sensitive material layer.

4) Exposing the photo-sensitive material layer to a second radiation having a maximum intensity at the second wavelength to form a second latent pattern in the photo-sensitive material layer. And, finally,

5) Simultaneously removing the first latent pattern and the second latent pattern in the photo-sensitive material layer to form a dual damascene structure in the photo-sensitive material layer.

It is to be understood that both the foregoing general description and the following detailed description are exemplary, but are not restrictive, of the invention.

### BRIEF DESCRIPTION OF DRAWINGS

FIG. 1 is a schematic diagram of a conventional dual damascene structure.

FIG. 2 to FIG. 8 are schematic diagrams showing a prior art process of fabricating a via-first dual damascene structure in a dielectric layer.

FIGS. 9, 10, and 12 to 15 are schematic diagrams of a preferred embodiment according to the present invention.

FIG. 11 depicts a relation diagram regarding the absorbance characteristics of KrF photoresist vs. wavelength of an exposure radiation in the preferred embodiment according to the present invention.

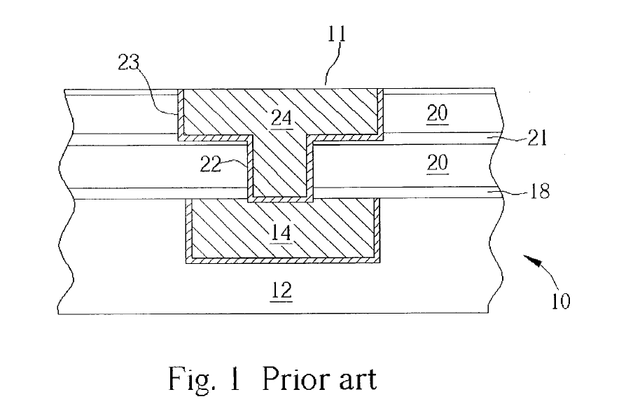

### DETAILED DESCRIPTION

The process steps and structures described below do not form a complete process flow for manufacturing integrated circuits. The present invention can be practiced in conjunction with integrated circuit fabrication techniques currently used in the art, and only so much of the commonly practiced process steps are included as are necessary for an understanding of the present invention.

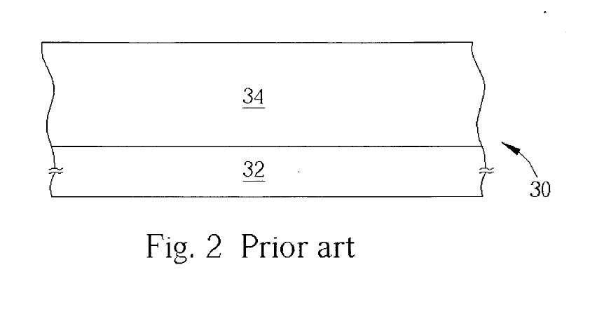

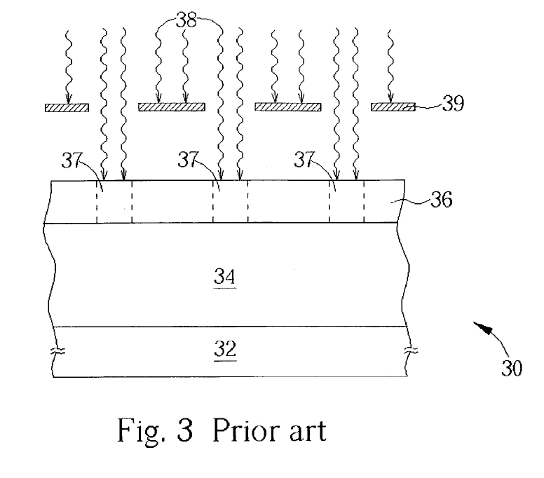

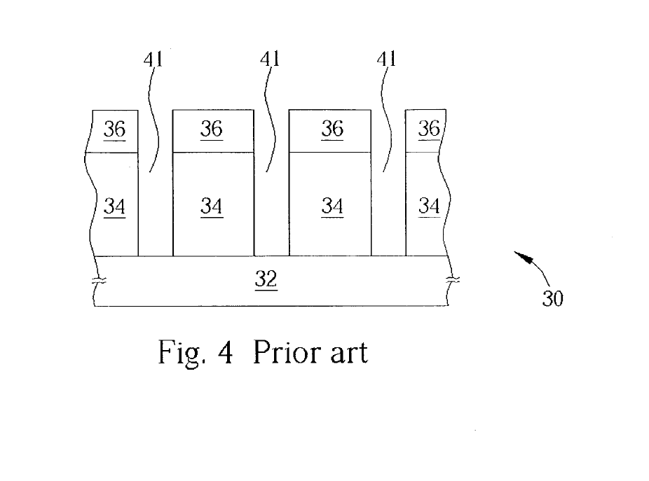

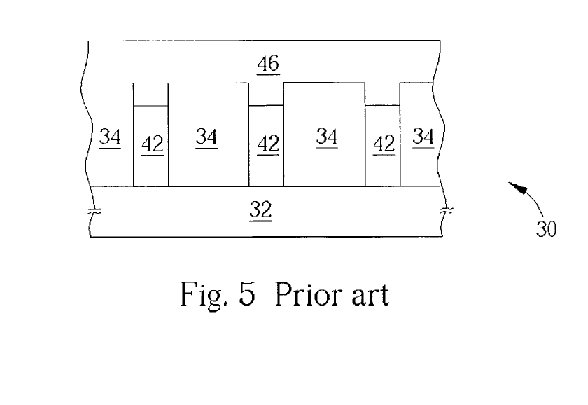

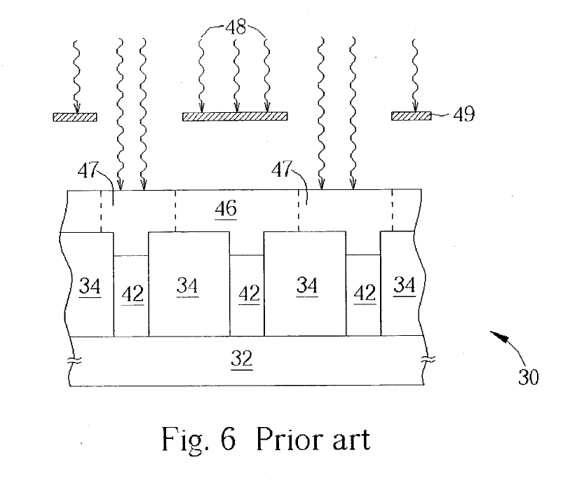

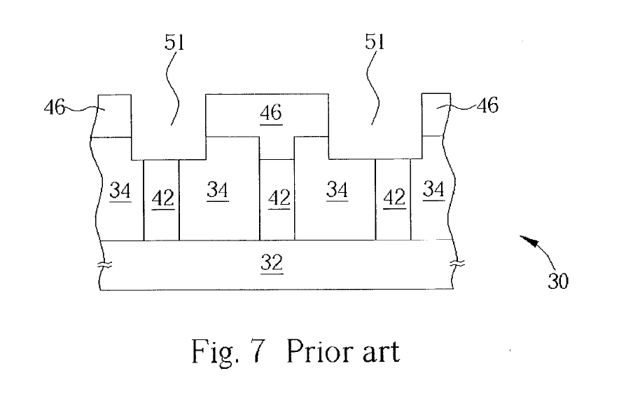

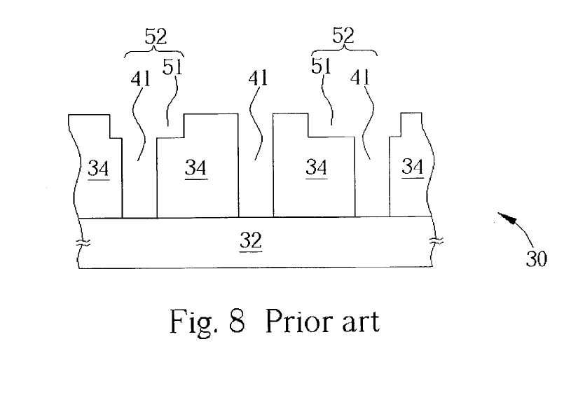

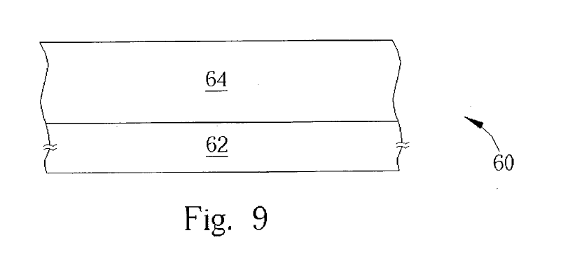

Referring to FIG. 9 to FIG. 15, a dual damascene structure formed according to the preferred embodiment of the present invention will now be described in detail. First, as shown in FIG. 9, a semiconductor wafer 60 comprising a bottom layer 62 and a several micrometers thick dielectric layer 64 formed over the bottom layer is provided. The bottom layer 62 may be a semiconductor substrate or another dielectric layer, and devices and/or interconnects previously formed in the bottom layer 62 are omitted in FIG. 2 to FIG. 15 for simplicity. The dielectric constant of the dielectric layer 64 typically ranges from 2.2 to 3.5. Preferably, a suitable material for the dielectric layer 64 may include FLARE™, SiLK™, poly (arylene ether) polymer, HSQ (hydrogen silsesquioxane), MSQ (methyl silsesquioxane), HOSP (hybrid-organic-siloxane-polymer), parylene, or porous SiO₂.

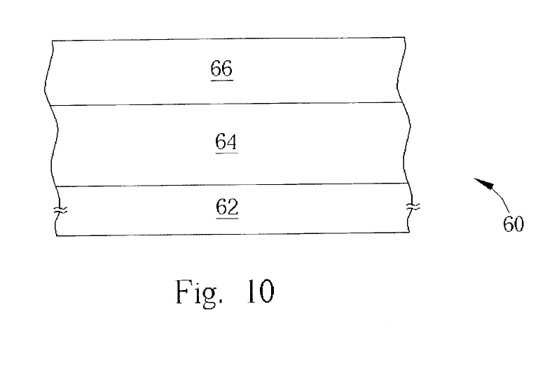

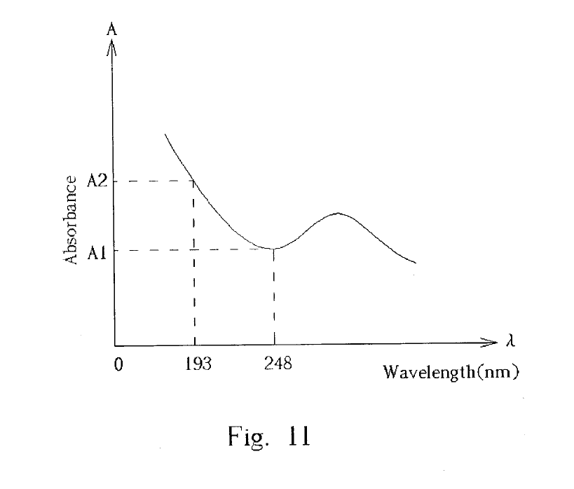

As shown in FIG. 10, a positive photoresist layer 66 is spin-coated onto the dielectric layer 64. Preferably, the positive photoresist layer 66 has a thickness of between 0.5 to 3.5 μm, more preferably between 1 to 2.5 μm, and most preferably 2 μm. In the preferred embodiment, the positive photoresist layer 66 is composed of a KrF (248 nm) photoresist. In other embodiments according to the present invention, however, the positive photoresist layer 66 may be composed an i-line (365 nm) photoresist, an ArF (193 nm) photoresist, or a 157 nm photoresist, or other photo-sensitive photoresists. The positive photoresist layer 66 presents different absorbance characteristics to different wavelengths of light. As shown in FIG. 11, the positive KrF photoresist layer 66 presents a first absorbance A1 at 248 nm, and presents a second absorbance A2 for a 193 nm deep UV light. For KrF photoresist, the first absorbance A1 is less than the second absorbance A2. A 90-130° C. soft bake step is thereafter used to enhance the precision of the pattern for about 1 minute.

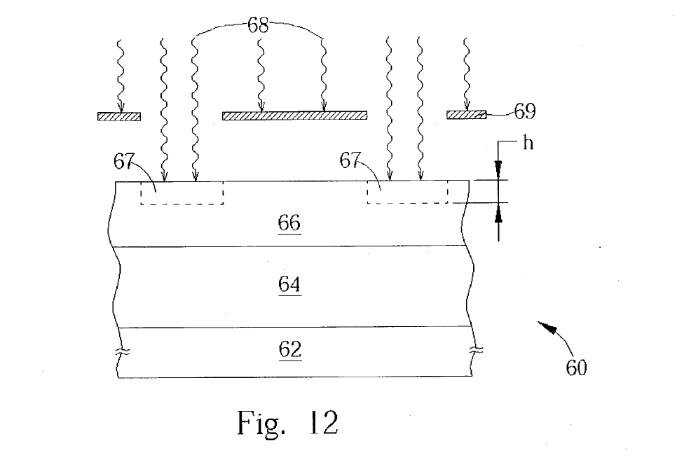

As shown in FIG. 12, a latent trench pattern 67 is then created in the positive photoresist layer 66 using a mask 69 having a trench pattern and incident exposure rays 68 at 193 nm. The latent trench pattern 67 is formed due to the low transmittance of the positive photoresist layer 66 at 193 nm exposure rays 68. As noted, KrF photoresist presents a greater absorbance A2 at 193 nm, which in turn, represents a smaller transmittance at 193 nm (transmittance is defined as an inverse of an absorbance). Consequently, 193 nm light can only reach and expose a predetermined depth of the KrF positive photoresist layer 66 and react with portions of the photoresist molecules near the top surface. In the preferred embodiment of the present invention, the predetermined depth is about 0.2 μm for a 2 μm thick KrF positive photoresist layer 66 after the exposure to 193 nm exposure rays 68.

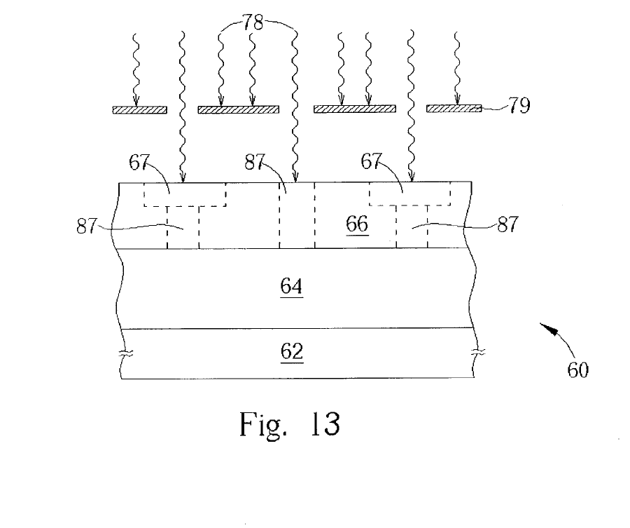

As shown in FIG. 13, after finishing the 193 nm exposure of the KrF positive photoresist layer 66, the light source is altered to 248 nm. A latent via pattern 87 is consecutively created in the positive photoresist layer 66 using a mask 79 having a via pattern and incident exposure rays 78 at 248 nm. The 248 nm UV light can expose through the entire thickness of the positive photoresist layer 66 due to a greater transmittance, i.e. a smaller absorbance, at 248 nm. It should be noted that the time interval between the first exposure (trench pattern exposure) and the second exposure (via pattern exposure) should be as small as possible to minimize critical dimension (CD) variation resulting from photo active compounds (PACs).

In another embodiment according to the present invention, a via pattern exposure may be done first, followed by the trench pattern exposure step. However, it is preferable to execute a larger area exposure first, then a smaller area, since critical dimension (CD) variations resulting from PACs may be significant with light exposing small areas, thus producing undesirable results.

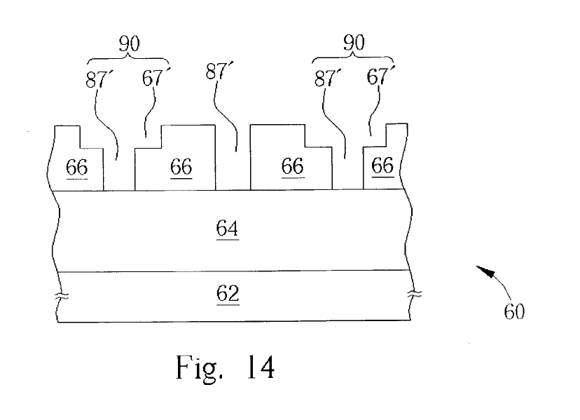

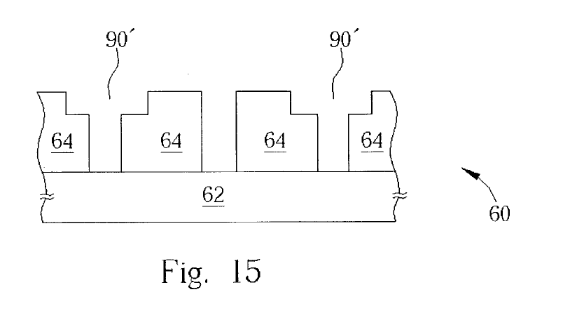

Thereafter, a developer containing tetramethyl ammonium hydroxide or choline is used to develop and wash away the latent trench pattern 67 and the latent via pattern 87, simultaneously. As shown in FIG. 14, after development, a dual damascene structure 90 having a trench structure 67″ and a via structure 87″ is completed in the KrF positive photoresist layer 66. Next, a 90-130° C. hard bake step, performed for about 1 minute, is thereafter used to enhance the precision of the pattern. As shown in FIG. 15, using the developed and baked positive photoresist layer 66 as an etch mask, an anisotropic etching process is performed to transfer the trench structure 67″ and the via structure 87″ in the photoresist layer 66 to the underlying dielectric layer 64, so as to form a dual damascene structure 90″ in the dielectric layer 64. Finally, the positive photoresist layer 66 is removed using known skills in the art, such as a plasma ashing technique.

After the formation of the dual damascene structure 90″ in the dielectric layer 64, the preferred embodiment may further comprise the following metallization steps (not shown in the Figs.: (1) sputtering a barrier layer onto the dielectric layer 64; (2) depositing a layer of metal on the barrier layer, the metal layer filling the dual damascene structure 90″; (3) performing a chemical-mechanical-polishing (CMP) process to planarize the metal layer; and (4) coating a passivation layer on the metal layer.

In comparison with the prior art method, the present invention only requires one photoresist coating step, two consecutive exposure steps, one development step, and one etching step to complete a dual damascene structure in a dielectric layer. The step of the BARC etch block formation in the prior art method is eliminated in the present invention. A person skilled in the art may apply the present invention to a wide scope of dual damascene processes, such as a via-first dual damascene process, a trench-first dual damascene process, a buried etch stop dual damascene process, or a buried etch mask dual damascene process according the above disclosure.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A method for fabricating a dual damascene structure with duplicate consecutive exposures, the method comprising:
providing a semiconductor substrate;
forming a photo-sensitive material layer over the semiconductor substrate, wherein the photo sensitive material layer presents a first absorbance at a first wavelength and presents a second absorbance at a second wavelength upon exposure to an incident light;
exposing the photo-sensitive material layer to a first radiation having a maximum intensity at the first wavelength to form a first latent pattern in the photo-sensitive material layer;
exposing the photo-sensitive material layer to a second radiation having a maximum intensity at the second wavelength to form a second latent pattern in the photo-sensitive material layer; and
simultaneously removing the first latent pattern and the second latent pattern in the photo-sensitive material layer to form a dual damascene structure in the photo-sensitive material layer.

2. The method of claim 1 wherein the photo-sensitive material layer is a photoresist layer.

3. The method of claim 2 wherein the photoresist layer is composed of i-line photoresist.

4. The method of claim 2 wherein the photoresist layer is composed of KrF photoresist.

5. The method of claim 2 wherein the photoresist layer is composed of ArF photoresist.

6. The method of claim 2 wherein the photoresist layer is composed of 157 nm photoresist.

7. The method of claim 1 wherein the photo-sensitive material layer is formed on a dielectric layer of the semiconductor substrate.

8. The method of claim 1 wherein the first latent pattern and the second latent pattern in the photo-sensitive material layer are removed by using a developer.

9. The method of claim 1 wherein the first wavelength is less than the second wavelength, and the first absorbance is greater than the second absorbance.

10. The method of claim 1 wherein the first latent pattern is a latent trench pattern and the second latent pattern is a latent via pattern.

11. A dual damascene interconnection process, the process comprising:
providing a semiconductor substrate, a dielectric layer formed on the semiconductor substrate;
coating a photoresist layer on the dielectric layer;
performing a first exposure to form a first latent pattern in the photoresist layer;
thereafter performing a second exposure to form a second latent pattern in the photoresist layer, wherein the photoresist layer presents a first absorbance for the first exposure and a second absorbance for the second exposure;
simultaneously removing the first latent pattern and the second latent pattern in the photoresist layer to form a dual damascene structure in the photoresist layer;
performing an anisotropic etching process to transfer the dual damascene structure in the photoresist layer to the underlying dielectric layer; and
removing the photoresist layer.

12. The process of claim 1 wherein after removing the photoresist layer, the process further comprises:
sputtering a barrier layer onto the dielectric layer;
depositing a layer of metal on the barrier layer, the metal layer filling the dual damascene structure;
performing a chemical-mechanical-polishing (CMP) process to planarize the metal layer;
coating a passivation layer on the metal layer.

13. The process of the claim 111 wherein the first exposure uses a first radiation having a maximum intensity at a first wavelength and the second exposure uses a second radiation having a maximum intensity at a second wavelength.

14. The process of the claim 11 wherein the first absorbance is not equal to the second absorbance.

15. The process of the claim 11 wherein the first absorbance is less than the second absorbance.

16. The method of claim 11 wherein the photoresist layer is composed of i-line photoresist.

17. The method of claim 11 wherein the photoresist layer is composed of KrF photoresist.

18. The method of claim 11 wherein the photoresist layer is composed of ArF photoresist.

19. The method of claim 11 wherein the photoresist layer is composed of 157 nm photoresist.

20. The method of claim 11 wherein the first latent pattern is a latent trench pattern and the second latent pattern is a latent via pattern.
